(19) United States
(12) Patent Application Publication
(10) Pub. No.: US 2024/0242531 A1
(43) Pub. Date: Jul. 18, 2024

(54) THIN, MULTI-LENS, OPTICAL FINGERPRINT SENSOR ADAPTED TO IMAGE THROUGH CELL PHONE DISPLAYS

(71) Applicant: OmniVision Technologies, Inc., Santa Clara, CA (US)

(72) Inventors: Tsung-Wei WAN, Hsinchu City (TW); Wei-Ping CHEN, Hsinchu City (TW); Jau-Jan DENG, Hsinchu City (TW); Kuang-ju WANG, Hsinchu City (TW)

(21) Appl. No.: 18/622,722

(22) Filed: Mar. 29, 2024

Related U.S. Application Data
(63) Continuation of application No. 17/150,827, filed on Jan. 15, 2021.

(51) Int. Cl. G06V 40/13; G02B 3/00; G02B 5/00; G06V 40/12

(52) U.S. Cl. CPC G06V 40/1318; G02B 3/0037; G02B 5/003; G06V 40/1347; G06V 40/1365

(57) ABSTRACT

A multiple-lens optical fingerprint reader for reading fingerprints through a display has an image sensor integrated circuit with photosensor array(s); a spacer; and multiple lenses in a microlens array, each lens of multiple lenses focuses light arriving at that lens from a finger adjacent the display through the spacer to form an image on associated photosensors on a photosensor array of the integrated circuit. A method of verifying identity of a user includes illuminating a finger of the user with an OLED display; focusing light from the fingerprint through arrayed microlenses onto a photosensor array of an integrated circuit, reading the array to overlapping electronic fingerprint images; extracting features from the overlapping electronic fingerprint images or from a stitched fingerprint image, and comparing the features to features of at least one user in a library of features and associated with one or more fingers of one or more authorized users.

### RELATED APPLICATIONS

This application is a Continuation of U.S. patent application Ser. No. 17/150,827 filed Jan. 15, 2021, which is incorporated herein by reference in its entirety.

### BACKGROUND

Many modern cell phone operating systems, including Apple iOS and Android, are configurable to use biometrics, such as fingerprints, as an alternative to user entry of unlock codes to validate user identity. A prior optical sensor for reading fingerprints used an electronic camera equipped with a single lens and an image sensor with a single array of photosensors to image a fingerprint surface of a finger through an OLED cell-phone display. To image a reasonable area of the finger, the lens and array of photosensors were large and required considerable space between lens and the array of photosensors—posing issues in the limited space available in a cell phone.

### SUMMARY

In an embodiment, a multiple-lens optical fingerprint reader adaptable to read fingerprints through a display has an image sensor integrated circuit comprising at least one photosensor array; a spacer; and a plurality of lenses organized in a microlens array, each lens of the plurality of lenses being configured to focus light arriving at that lens from a portion of a fingerprint region of a finger adjacent a surface of the display through the spacer to form an image on a plurality of photosensors associated with that lens, the photosensors being of a photosensor array of the at least one photosensor array, the image being formed independently of other lenses of the plurality of lenses.

In another embodiment, a method of verifying identity of a user includes illuminating a fingerprint region of a finger of the user with an organic light emitting diode display; focusing light from the fingerprint region through an array of microlenses onto at least one photosensor array of an integrated circuit, each microlens focusing light from a portion of the fingerprint region onto multiple photosensors of the at least one photosensor arrays; reading the at least one photosensor array to form overlapping electronic fingerprint images; extracting features by a method selected from extracting features from the overlapping electronic fingerprint images and extracting features from a stitched image formed from the overlapping electronic fingerprint images; and comparing the features to features of at least one user in a library of features associated with one or more fingers of one or more authorized users.

In an embodiment, the fingerprint s reader is made by forming an infrared filter on a bottom side of a thin glass substrate, the glass substrate being from 0.1 mm and 0.15 mm in thickness; depositing a light-absorbing coating on the infrared filter; masking and etching the light absorbing coating to form openings; forming an array of microlenses by reflowing reflowable optical material onto a top side of the glass substrate and shaping the optical material with a preformed wafer-sized stamp; aligning, and bonding the substrate to a wafer of integrated circuits, each of the integrated circuits having at least one array of photosensors; dicing the wafer of integrated circuits; and bonding the integrated circuits to a flexible printed circuit.

### BRIEF DESCRIPTION OF THE FIGURES

FIG. 1 is a top view of an optical fingerprint sensor module configured for placement beneath an OLED cell phone display and having a 4×6 array of microlenses and a spacer atop an image sensor, and a circuit board.

FIG. 2 is a cross sectional diagram of a finger, OLED display, the optical fingerprint sensor module of FIG. 1 taken along line A-A in FIG. 1, and a battery; the optical fingerprint sensor module having a microlens array, spacer, image sensor, and a flexible circuit board.

FIG. 3 is an enlarged copy of a portion of FIG. 2, showing overlapping fields of view of image sensor photodiode arrays with traced light paths.

FIG. 4 is a flowchart illustrating a method for fabrication of the optical fingerprint sensor.

FIG. 5 is a flowchart illustrating a method for how the optical fingerprint sensor is used.

FIG. 6 is a block diagram illustrating a cellular telephone device in which the optical fingerprint sensor may be used.

### DETAILED DESCRIPTION OF THE EMBODIMENTS

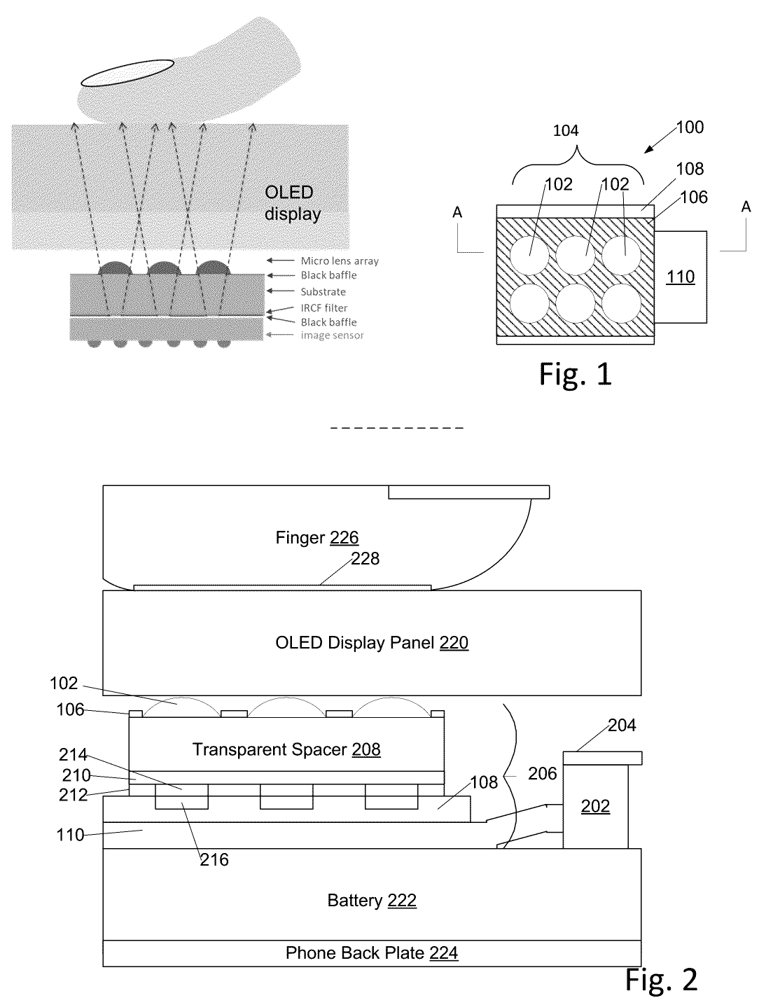

A fingerprint sensor module 100 (FIG. 1) has a microlens array 104 of microlenses 102, in this example a 2×3 array. In other examples, it is anticipated that the microlens array may have other numbers of lenses, such a 3×3, 3×6, 4×4, 4×8, 6×6, 6×8, 6×10, or larger lens array. The microlenses 102 of the microlens array 104 are surrounded by a black mask 106. The lens array 104 and black mask 106 are mounted atop a transparent spacer (208 in FIG. 2) mounted atop an image sensor integrated circuit 108 that may in some embodiments also include other functions such as processor and memory functions. The image sensor integrated circuit 108 may in some embodiments be mounted directly to a processor printed circuit board of a cell phone or other fingerprint-activated unit, or in other embodiment be mounted to a flexible printed circuit 110 that extends beyond integrated circuit 108 so it may be coupled to a connector, such as connector 202 (FIG. 2) attached to a processor printed circuit board 204 of a cell phone or other fingerprint-activated or fingerprint-detecting unit. Fingerprint sensor module 100, 206 has the flexible printed circuit 110 that may couple through connector 202 to other components of the phone.

Under the spacer 208, in infrared-sensing embodiments, there may be an infrared filter 210, which is omitted in other embodiments that image fingerprints with visible light. There is also an opaque, black, mask 212 with openings 214 that align with photosensor arrays 216 of integrated circuit 108

In a typical application, the optical fingerprint sensor module 100 is positioned under an organic light-emitting diode (OLED) display panel 220 of the cell phone, the OLED display panel 220 being of a known thickness and at least semitransparent to light at infrared wavelengths if infrared filter 210 is present, or semitransparent to some visible light wavelengths if infrared filter 210 is absent.

The optical fingerprint sensor module 100 is also typically positioned in front of a battery 222 that is positioned in front of a back plate 224 of the cell phone, the distance from a back side of back plate 224 to a front side of the OLED display panel 220 defining thickness of the cell phone.

When a finger 226 of a user is positioned in contact with the front of the OLED display panel 220, some light reflected from a fingerprint region 228 of the finger 226 passes through OLED display panel 220 and is focused by microlenses 102 onto photosensor arrays 216.

In an embodiment, each microlens 102 of the lens array as an aspheric single-element lens with distance from a front surface of the lens between 1.5 mm and 2.1 mm, Fstop of 1.0, a field of view FOV=23°, and an effective focal length EFFL=0.113 mm. Each lens is 0.09935 mm in diameter and 0.0526 mm tall.

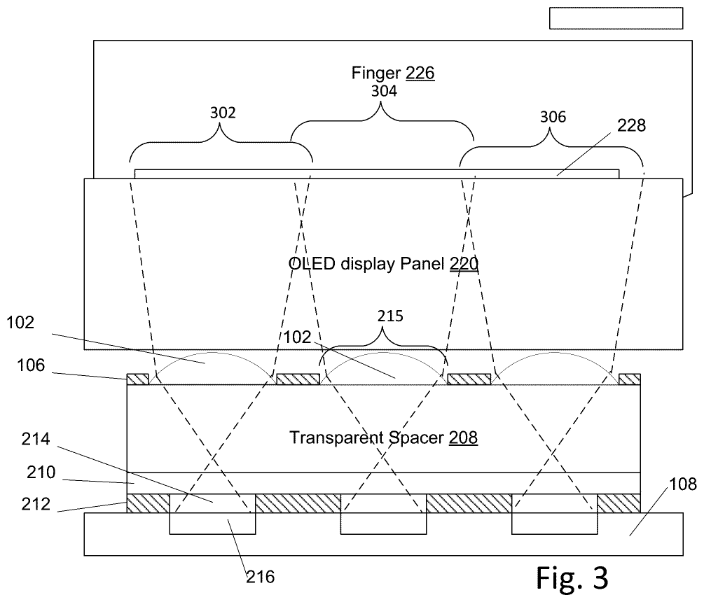

As illustrated in FIG. 3, each microlens 102 of the microlens array 104 images a portion 302, 304, 306 of the fingerprint region 228 of finger 226 and produces an image on a separate photosensor array 216 of integrated circuit 108 of that portion of the fingerprint region. In an embodiment, the portion 302, 304, 306 of the fingerprint region 228 of finger 226 that each lens images onto the photosensor array 216 is centered directly above, but is larger than, the photosensor array. In an embodiment, each photosensor array typically is at least a 100×100 array of photosensors. In an alternative embodiment, all the lenses project images onto a single array of at least 400×400 photosensors, where the lenses of the lens array each project its image onto a separate area of the single array of photosensors.

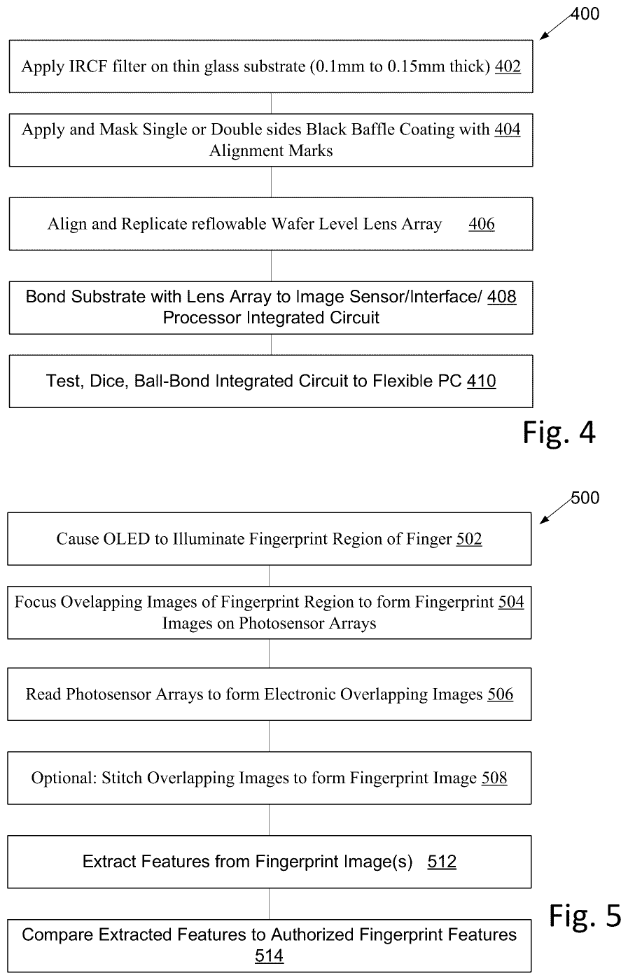

The fingerprint sensor module 100 is produced by a process 400 according to FIG. 4. The infrared filter 210 is deposited 402 on a bottom side of a thin glass substrate that will become spacer 208 of between 100 um and 150 um thickness (inclusive). Black light-absorbing coatings, or masks, 212 are then deposited 404 on the bottom side of the glass substrate 208, if the infrared filter 210 is present the light-absorbing coating 212 is deposited over the infrared filter 210. In some embodiments black light-absorbing coating 106 is also deposited on a top side of the glass substrate or spacer 208. The bottom black light absorbing coating 212, and top light absorbing coating 106 if used, are then masked and etched to form openings 214, 215 and alignment marks (not shown), these black coatings form baffles that improve image quality when lenses are formed with small pitch and large image overlap areas.

The microlens array 104 is formed 406 as a wafer level lens array by reflowing reflowable optical material onto a top side of the glass substrate or spacer 208 and the reflowable optical material is shaped with a preformed wafer-sized stamp. The alignment marks are used to align the stamp and optical material with the previously formed openings 214, 215 in the light absorbing coating. The bottom side of the glass substrate or spacer 208 with light absorbing coating 212 is then aligned, and bonded 408, to a wafer of integrated circuits 108. The assembled wafer with microlenses 102, glass substrate serving a spacer 208, and integrated circuits 108 may be tested and defective circuits inked. The assembled wafer is then diced, typically by sawing, and individual microlens array 104, substrate or spacer 208, light absorbing coatings 106, 212, and integrated circuit 108 assemblies bonded 410 using a ball-bond reflow technique to flexible printed circuit 110.

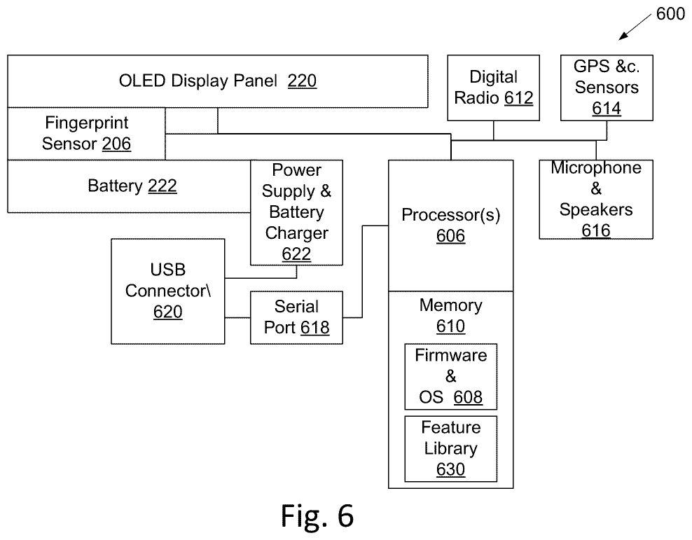

The fingerprint sensor module 100, 206 is used in a cellular telephone 600 (FIG. 6); the cellular telephone 600 incorporates OLED display panel 220, typically having touch sensing capability, operable under control by one or more processors 606 coupled to receive raw images or extracted features from fingerprint sensor 206. On or more processors 606 operate under control of firmware and an operating system 608 in a memory system 610, and are also coupled to one or more digital radios 612 configured for two-way communications with at least digital cellular towers. The processors 606 are also coupled to a global positioning system receiver and other sensors 614 such as accelerometers, a microphone and speaker 616, and in many embodiments a serial port 618 coupled to a universal serial bus (USB) interface 620. Cellular telephone 600 is powered by the battery 222, through a power supply circuit and recharged by a charger 622.

The fingerprint sensor is operated by a method 500 (FIG. 5) including illuminating 502 the fingerprint region 118 of the finger 226 using the OLED display panel 220; light from the fingerprint region 228 is focused by microlenses 102 onto the photosensor arrays 216 of integrated circuit 108, each microlens 102 focuses light onto multiple photosensors of the photosensor arrays. The photosensor arrays are then read 506 to form overlapping electronic fingerprint images. The overlapping electronic fingerprint images may in some embodiments then be stitched 508 to form a single electronic fingerprint image. Features are then extracted 512 from the single electronic fingerprint image or from the overlapping electronic fingerprint images, these features are then compared 514 to features associated with one or more users in a feature library 630 of features comprising features associated with one or more fingers of one or more authorized users in memory system 610, a successful comparison verifies identity of a user to whom finger 226 belongs.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A method of making a fingerprint reader comprising:
forming an infrared filter on a bottom side of a thin glass substrate, the thin glass substrate being from 0.1 mm and 0.15 mm in thickness;
depositing a light-absorbing coating on the infrared filter;
masking and etching the light-absorbing coating to form a first plurality of openings;
forming an array of microlenses by reflowing reflowable optical material onto a top side of the thin glass substrate and shaping the reflowable optical material with a preformed wafer-sized stamp;
aligning, and bonding the thin glass substrate to a wafer of integrated circuits, each of the integrated circuits having at least one array of photosensors; and
dicing the wafer of integrated circuits to form fingerprint sensors each having a plurality of the microlenses.

2. The method of claim 1 further comprising bonding the integrated circuits to a flexible printed circuit.

3. The method of claim 1 wherein the array of microlenses and the at least one array of photosensors are configured such a field of view of each microlens is above an image formed on a plurality of photosensors associated with that microlens.

4. The method of claim 3 wherein each integrated circuit of the wafer of integrated circuits comprises a processor configured to stitch the images associated with a plurality of the microlenses.

5. The method of claim 1 wherein the array of microlenses and the at least one array of photosensors are configured such a field of view of each microlens is centered directly above an image formed on a plurality of photosensors associated with that microlens.

6. The method of claim 1 further comprising:
depositing a black mask on a top side of the thin glass substrate;
masking and etching the black mask to form a second plurality of openings; and
wherein each microlens is centered in an opening of the second plurality of openings.

7. The method of claim 6 wherein each microlens is centered over an opening of the first plurality of openings.

8. The method of claim 7 further comprising:
depositing a black mask on a top side of the thin glass substrate;
masking and etching the black mask to form a second plurality of openings; and
wherein each microlens is centered in an opening of the second plurality of openings.

9. The method of claim 1 further comprising:
depositing a black mask on a top side of the thin glass substrate;
masking and etching the black mask to form a second plurality of openings; and
wherein each microlens is centered in an opening of the second plurality of openings.

10. The method of claim 9 wherein each microlens is centered over an opening of the first plurality of openings.

11. The method of claim 10 wherein the array of microlenses and the at least one array of photosensors are configured such a field of view of each microlens is above an image formed on a plurality of photosensors associated with that microlens.

12. The method of claim 11 wherein each integrated circuit of the wafer of integrated circuits comprises a processor configured to stitch the images associated with a plurality of the microlenses.
